(19) United States
(12) Patent Application Publication
(10) Pub. No.: US 2015/0280050 A1
(43) Pub. Date: Oct. 1, 2015

(54) METHOD OF MAKING PHOTOVOLTAIC DEVICE THROUGH TAILORED HEAT TREATMENT

(71) Applicant: Chen-Yun Wang, Kaohsiung City (TW)

(72) Inventor: Chen-Yun Wang, Kaohsiung City (TW)

(73) Assignee: TSMC SOLAR LTD., Taichung City (TW)

(21) Appl. No.: 14/227,063

(22) Filed: Mar. 27, 2014

(51) Int. Cl. H01L 31/18

(52) U.S. Cl. CPC H01L 31/1884; H01L 31/1864

(57) ABSTRACT

A method of fabricating a photovoltaic device includes a step of forming an absorber layer above a substrate of the photovoltaic device, a step of forming a buffer layer over the absorber layer, and a step of pre-heating the photovoltaic device at a first heating rate to a selected temperature. The first heating rate being higher than 5° C./minute. The method further includes a step of forming a front contact layer over the buffer layer at the selected temperature, after the step of pre-heating the photovoltaic device.

### PRIORITY CLAIM AND CROSS-REFERENCE

None.

### BACKGROUND

The disclosure relates to photovoltaic devices generally, and more particularly relates to a method for making a photovoltaic device, and the resulting photovoltaic device having high power and high quantum efficiency.

Photovoltaic devices (also referred to as solar cells) absorb sun light and convert light energy into electricity. Photovoltaic devices and manufacturing methods therefore are continually evolving to provide higher conversion efficiency with thinner designs.

Thin film solar cells are based on one or more layers of thin films of photovoltaic materials deposited on a substrate. The film thickness of the photovoltaic materials ranges from several nanometers to tens of micrometers. Examples of such photovoltaic materials include cadmium telluride (CdTe), copper indium gallium selenide (CIGS) and amorphous silicon (α-Si). These materials function as light absorbers. A photovoltaic device can further comprise other thin films such as a buffer layer, a back contact layer, and a front contact layer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. Like reference numerals denote like features throughout specification and drawings.

FIGS. 1A-1D are cross-sectional views of a portion of an exemplary photovoltaic device during fabrication, in accordance with some embodiments.

FIG. 2A is a flow chart diagram illustrating a method of fabricating an exemplary photovoltaic device in accordance with some embodiments.

FIGS. 3A-3B illustrate a heating profile before and during the step of forming a front contact layer in some embodiments.

FIGS. 4A-4B illustrate a heating profile before and during the step of forming a front contact layer in accordance with some embodiments.

FIG. 5 compares the results of the power of a resulting photovoltaic device when two different heating rates are used, respectively, before the step of forming a front contact layer in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

This description of the exemplary embodiments is intended to be read in connection with the accompanying drawings, which are to be considered part of the entire written description. In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

The quantum efficiency (QE), or incident photon to converted electron (IPCE) ratio, of a photosensitive device such as a solar cell, a photodiode and an image sensor is the percentage of photons incident to the device's photoreactive surface that produce charge carriers. QE indicates electrical sensitivity of the device to light. Internal Quantum Efficiency (IQE) is the ratio of the number of charge carriers collected by the solar cell to the number of photons that shine on the photovoltaic device from outside and are absorbed by the photovoltaic device.

In a thin-film photovoltaic device, a back contact layer is deposited over a substrate. An absorber layer is deposited over the back contact layer. A buffer layer comprising a suitable buffer material is disposed above an absorber layer. The buffer layer and the absorber layer, which both comprise a semiconductor material, provide a p-n or n-p junction. When the absorber layer absorbs sun light, electric current can be generated at the p-n or n-p junction.

This disclosure provides a method for fabricating a photovoltaic device, and a resulting photovoltaic device such as a thin film solar cell having high quantum efficiency and high power.

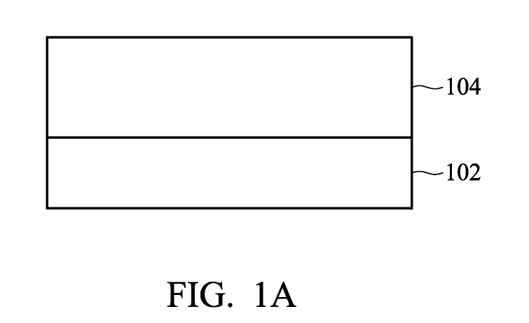

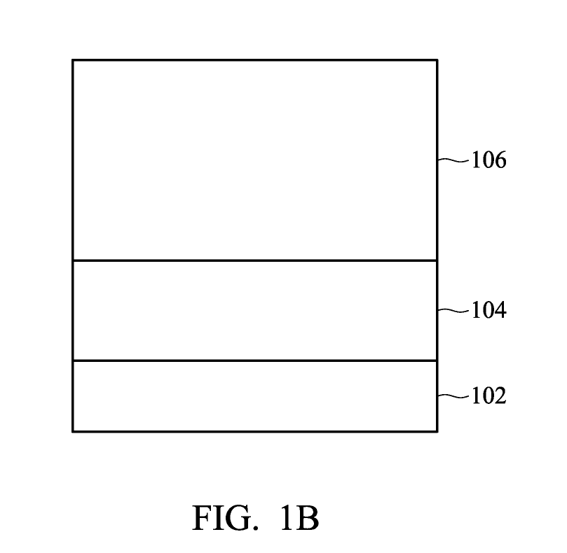

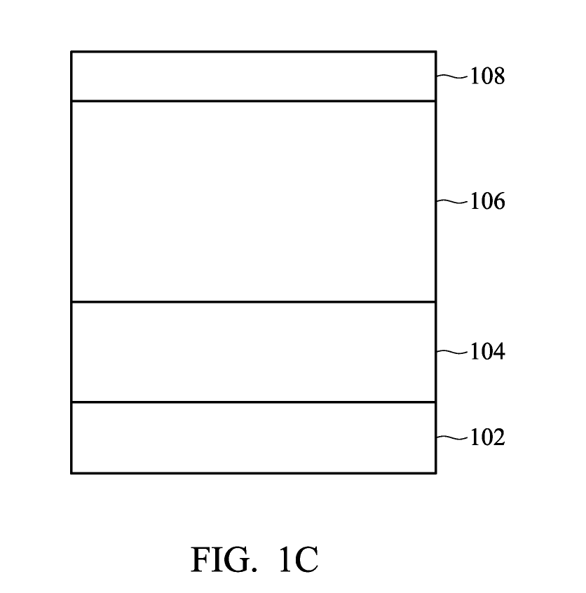

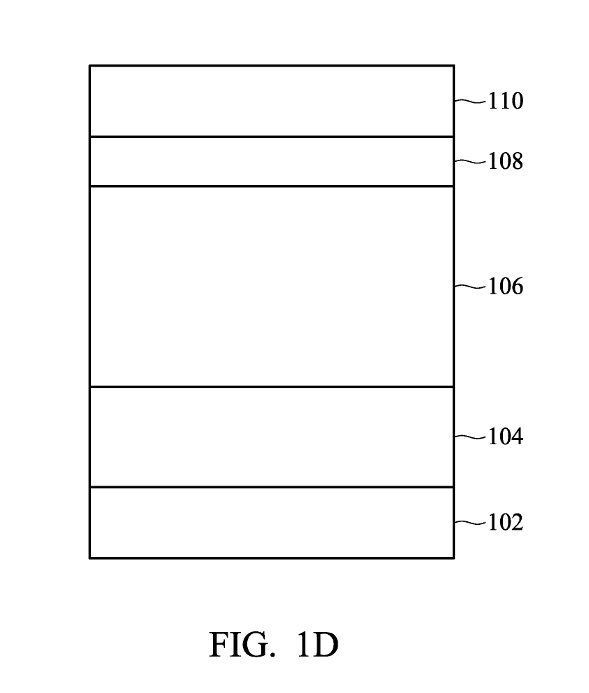

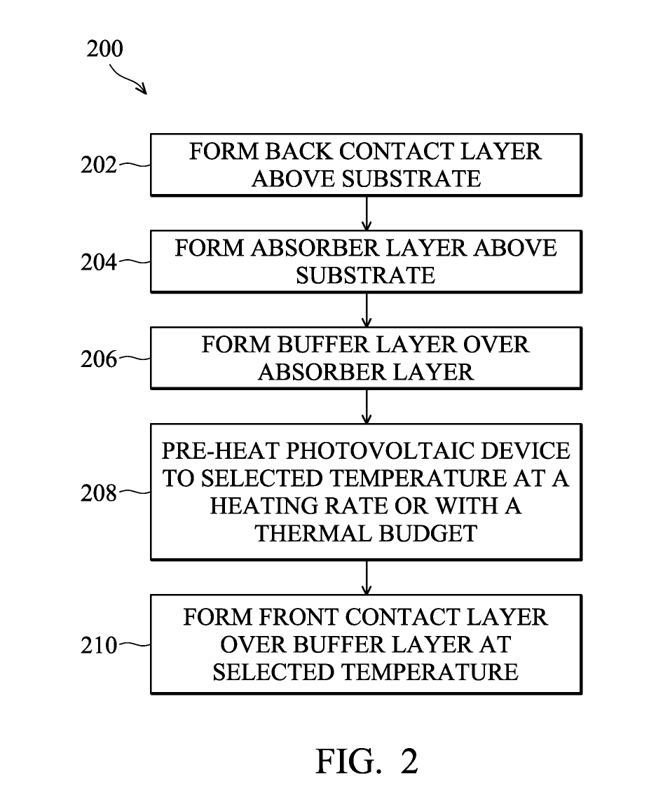

In FIGS. 1A-1D, like items are indicated by like reference numerals, and for brevity, descriptions of the structure, provided above with reference to the previous figures, are not repeated. The method described in FIG. 2 is described with reference to the exemplary structures described in FIGS. 1A-1D.

FIG. 2 illustrates an exemplary method 200 of fabricating an exemplary photovoltaic device 100 in accordance with some embodiments. FIGS. 1A-1D are cross-sectional views of a portion of an exemplary photovoltaic device 100 during fabrication in accordance with some embodiments.

At step 202, a back contact layer 104 is formed above a substrate 102. The resulting structure of a portion of a photovoltaic device 100 is illustrated in FIG. 1A.

Substrate 102 and back contact layer 104 are made of any material suitable for such layers in thin film photovoltaic devices. Examples of materials suitable for use in substrate 102 include but are not limited to glass (such as soda lime glass), polymer (e.g., polyimide) film and metal foils (such as stainless steel). The film thickness of substrate 102 is in any suitable range, for example, in the range of 0.1 mm to 5 mm in some embodiments.

In some embodiments, substrate 102 can comprise two or more layers. For example, substrate 102 can include a layer 101 (not shown) comprising glass, and a layer 103 (not shown) comprising silicon dioxide, which can be used to block possible diffusion of sodium in layer 101 comprising glass. In some embodiments, layer 101 comprises soda lime glass or other glass, which can tolerate a process at a temperature higher than 600° C. In some embodiments, layer 103 comprises silicon oxide having a formula SiOₓ, where x ranges from 0.3 to 2.

Examples of suitable materials for back contact layer 104 include, but are not limited to molybdenum (Mo), copper, nickel, or any other metals or conductive material. Back contact layer 104 can be selected based on the type of thin film photovoltaic device. For example, in a CIGS thin film photovoltaic device, back contact layer 104 is Mo in some embodiments. In a CdTe thin film photovoltaic device, back contact layer 104 is copper or nickel in some embodiments. The thickness of back contact layer 104 is on the order of nanometers or micrometers, for example, in the range from 100 nm to 20 microns. The thickness of back contact layer 104 is in the range of from 200 nm to 10 microns in some embodiments. Back contact layer 104 can be also etched to form a pattern.

At step 204, an absorber layer 106 comprising an absorber material is formed above back contact layer 104 and above substrate 102. The resulting structure of photovoltaic device 100 is illustrated in FIG. 1B.

Absorber layer 106 is a p-type or n-type semiconductor material. Examples of materials suitable for absorber layer 106 include but are not limited to cadmium telluride (CdTe), copper indium gallium selenide (CIGS), and amorphous silicon (α-Si). Absorber layer 106 can comprise material of a chalcopyrite family (e.g., CIGS) or kesterite family (e.g., BZnSnS and CZTS). In some embodiments, absorber layer 106 is a semiconductor comprising copper, indium, gallium and selenium, such as CuInₓGa₍₁₋ₓ₎Se₂, where x is in the range of from 0 to 1. In some embodiments, absorber layer 106 is a p-type semiconductor comprising copper, indium, gallium and selenium. Absorber layer 106 has a thickness on the order of nanometers or micrometers, for example, 0.5 microns to 10 microns. In some embodiments, the thickness of absorber layer 106 is in the range of 500 nm to 2 microns.

Absorber layer 106 can be formed according to methods such as sputtering, chemical vapor deposition, printing, electrodeposition or the like. For example, CIGS is formed by first sputtering a metal film comprising copper, indium and gallium at a specific ratio, followed by a selenization process of introducing selenium or selenium containing chemicals in gas state into the metal firm. In some embodiments, the selenium is deposited by evaporation physical vapor deposition (PVD).

Unless expressly indicated otherwise, references to “CIGS” or “CIGSS” made in this disclosure will be understood to encompass a material comprising copper indium gallium sulfide and/or selenide, for example, copper indium gallium selenide, copper indium gallium sulfide, and copper indium gallium sulfide/selenide. A selenide material may comprise sulfide or selenide can be completely replaced with sulfide.

In some embodiments, the absorber material in absorber layer 106 can be copper indium gallium selenide (CIGS) or copper indium gallium selenide/sulfide (CIGSS), cadmium telluride (CdTe), or any combination thereof. The absorber material is a p-type semiconductor. In some embodiments, the absorber material in absorber layer 106 can also be CuInSe₂, CuInS₂, CuGaSe₂, or CuInGa(Se, S)₂.

At step 206, a buffer layer 108 is formed over absorber layer 106. The resulting structure of a portion of photovoltaic device 100 during fabrication after step 206 is illustrated in FIG. 1C.

Examples of a suitable material in buffer layer 108 include but are not limited to CdS, CdSe, ZnS, ZnO, ZnSe, ZnIn₂Se₄, CuGaS₂, In₂S₃, MgO and Zn_{0.8} Mg_{0.2} O, and a combination thereof Such a buffer material can be an n-type semiconductor in some embodiments. The thickness of buffer layer 108 is on the order of nanometers, for example, in the range of from 5 nm to 100 nm in some embodiments.

Formation of buffer layer 108 is achieved through a suitable process such as sputtering or chemical vapor deposition. For example, in some embodiments, buffer layer 108 is a layer of CdS, ZnS or a mixture of CdS and ZnS, deposited through a hydrothermal reaction or chemical bath deposition (CBD) in a solution. For example, in some embodiments, a buffer layer 108 comprising a thin film of ZnS is formed above absorber layer 106 comprising CIGS. Buffer layer 108 is formed in an aqueous solution comprising ZnSO₄, ammonia and thiourea at 80° C. A suitable solution comprises 0.16M of ZnSO₄, 7.5M of ammonia, and 0.6 M of thiourea in some embodiments.

At step 208, photovoltaic device 100 is preheated to a selected temperature.

Photovoltaic device 100 is preheated at a first heating rate or with a thermal budget. In some embodiments, the selected temperature is in the range of from 150° C. to 200° C., for example, in the range of from 160° C. to 180° C. The selected temperature is the temperature of substrate 102 of photovoltaic device 100. A processing chamber, in which the preheating step 208 is performed, can have a same or higher temperature.

In some embodiments, method 200 can further comprise two additional steps before step 208 of preheating photovoltaic device 100. First, at a step 207, the processing chamber, in which the preheating step 208 is performed, is vacuumed. The vacuum level can be at 0.5 torr or lower, for example, at 0.2 torr. Second, at a step 209, an inert gas is provided into the processing chamber. Examples of a suitable inert gas include but are not limited to nitrogen, argon, or any other suitable gas or a combination thereof. In some embodiments, any one of step 207 and step 209 can be performed while step 208 is performed.

At step 208, in some embodiments, the first heating rate is higher than 5° C./minute, for example, in the range of from 5° C./minute to 25° C./minute. In some embodiments, the first heating rate is in the range of from 6° C./minute to 22° C./minute, for example, in the range of from 8° C./minute to 11° C./minute.

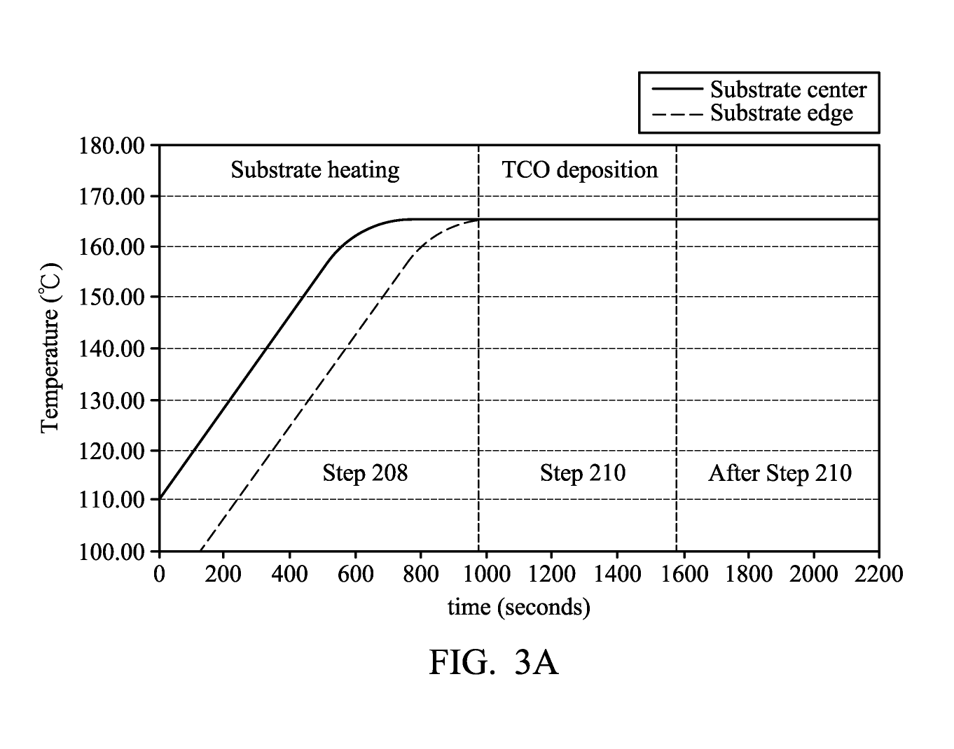

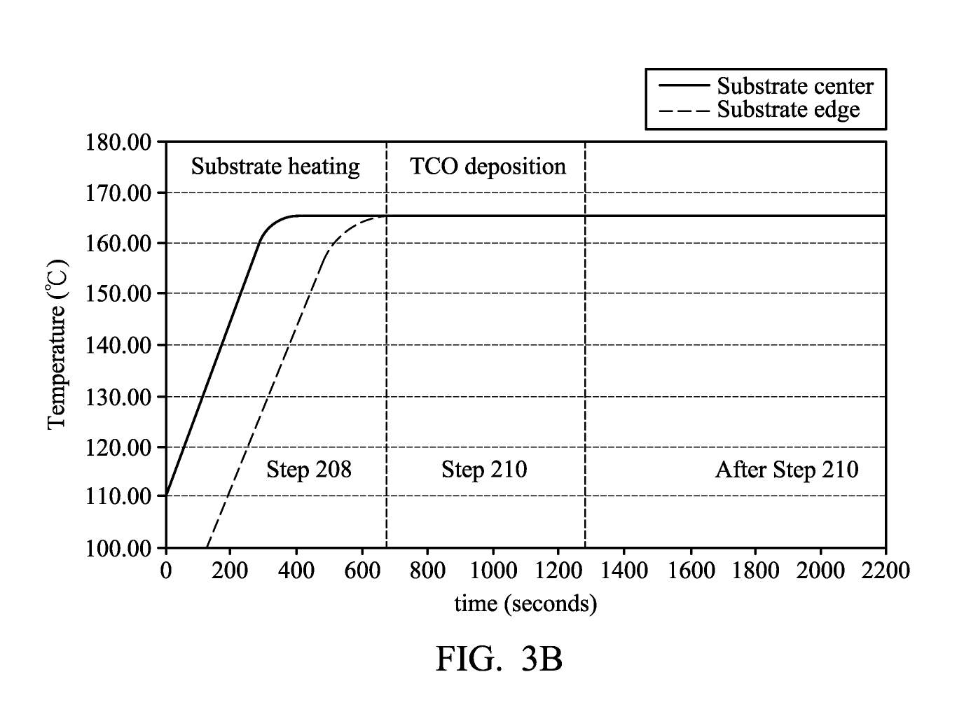

FIGS. 3A-3B illustrate a respective heating profile in some embodiments. As shown in FIG. 3A, the first heating rate is about 4-6° C./minute. A photovoltaic device being fabricated can include substrate 102, back contact layer 104, absorber layer 106 and buffer layer 108. Absorber layer 106 comprises copper indium gallium selenide/sulfide (CIGSS) in some embodiments. Such a photovoltaic device is disposed in a processing chamber, and then vacuumed to reach a level of 0.2 torr. Nitrogen gas is supplied into the processing chamber to reach a pressure level of 0.65 torr. Under a heating rate of about 4-6° C./minute, substrate 102 can be heated up to 165° C. The temperatures of an edge or the center of substrate 102 can be the same or different. For example, as shown in FIG. 3A, the temperature of an edge can be lower than that of the center. Both eventually reach to the same temperature (i.e. 165° C. in FIG. 3A). As illustrated in FIG. 3A, an exemplary time to reach the same temperature (i.e. pre-heating time) is about 960 seconds (16 minutes).

FIG. 3B illustrates a heating profile in accordance with some embodiments. An exemplary first heating rate is 8° C./minute or higher. The other conditions are identical to those described in FIG. 3A. As illustrated in FIG. 3B, an exemplary time for both the edge and the center of substrate 102 to reach the selected temperature (i.e. 165° C.) is about 600 seconds (10 minutes).

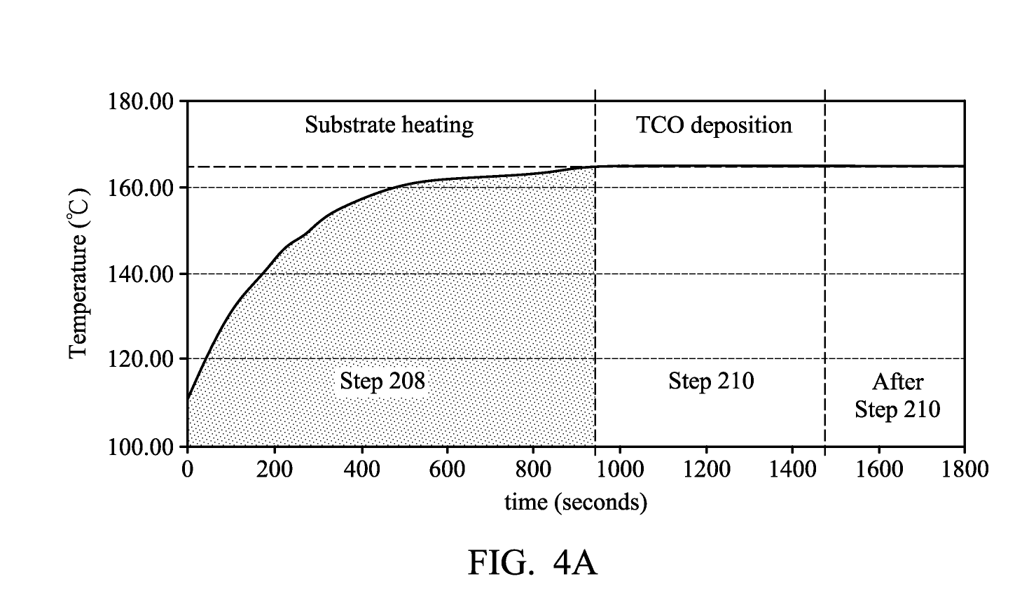

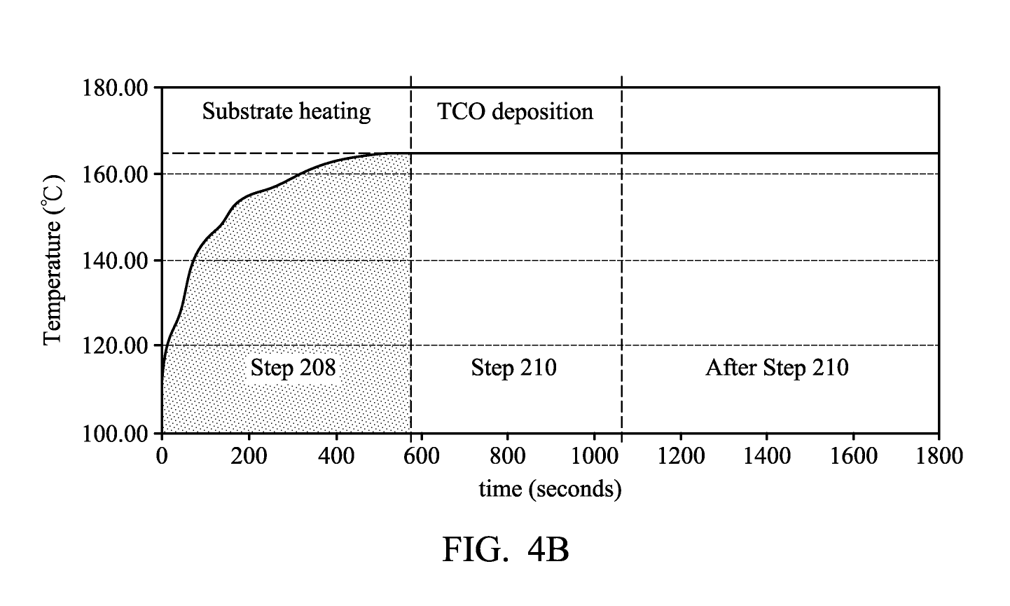

In some embodiments, photovoltaic device 100 is pre-heated to a selected temperature, with a thermal budget less than 150,000 degree*second. The thermal budget is defined as an integral of temperature (in ° C.) with respect to time (in seconds) during the pre-heating. The dimension of temperature in the thermal budget is in ° C. other than other units such as Kelvin. For example, when photovoltaic device 100 is pre-heated from an initial temperature T₀ to a selected temperature T₁ (in ° C.) in a time period oft (in seconds), the thermal budget is the integral of temperature (from T₀ to T₁ in ° C.) with respect to time t (in seconds). FIGS. 4A-4B illustrate a respect heating profile in some embodiments. As shown in FIGS. 4A-4B, for example, such a thermal budget can be calculated based on the area under a pre-heating profile of temperature versus time (i.e., the shaded areas in FIGS. 4A and 4B).

FIG. 4A is similar to FIG. 3A, except that the heating profile shows an overall temperature of substrate 102. As illustrated in FIG. 4A, an exemplary thermal budget is 170,000 degree*second or higher when the heating rate is about 4-6° C./minute. FIG. 4B is similar to FIG. 3B, except that the heating profile shows an overall temperature of substrate 102. As illustrated in FIG. 4B, an exemplary thermal budget is 130,000 degree*second or lower when the heating rate is 8° C./minute or lower. The values of these heating rate and thermal budget in FIGS. 3A-3B and 4A-4B are shown for the purpose of illustration.

In some embodiments, the thermal budget is in the range of from 30,000 degree*second to 150,000 degree*second, for example, in the range of from 35,000 degree*second to 125,000 degree*second. In some embodiments, the thermal budget is in the range of from 70,000 degree*second to 90,000 degree*second.

At step 210, a front contact layer 110 is formed over buffer layer 108 at the selected temperature after the step 208 of pre-heating the photovoltaic device. The resulting structure of a portion of photovoltaic device 100 is illustrated in FIG. 1D. Front contact layer 110 can be transparent. A front contact layer 110 can comprises transparent conductive oxide (TCO) or any other transparent conductive coating in some embodiments.

As a part of “window layer,” a layer 112 (not shown) comprising intrinsic ZnO (i-ZnO) can be disposed between front contact layer 110 and buffer layer 108. Layer 112 can be made of undoped i-ZnO, which is used to prevent short circuiting in the photovoltaic device 100. In thin film solar cells, film thickness of absorber layer 106 comprising an absorber material such as CdTe and copper indium gallium selenide (CIGS) ranges from several nanometers to tens of micrometers. Other layers such as buffer layer 108, back contact layer 104, and front contact layer 110 are even thinner in some embodiments. If front contact layer 114 and back contact layer 104 are unintentionally connected because of defects in the thin films, an unwanted short circuit (shunt path) will be provided. Such phenomenon decreases performance of the photovoltaic devices, and can cause the devices to fail to operate within specifications. The loss of efficiency due to the power dissipation resulting from the shunt paths can be up to 100%. In some embodiments, layer 112 comprising i-ZnO is thus provided to prevent short circuiting. Intrinsic ZnO having high electrical resistance can mitigate the shunt current and reduce formation of the shunt paths.

Front contact layer 110, which is a transparent conductive layer, is used in a photovoltaic (PV) device with dual functions: transmitting light to an absorber layer while also serving as a front contact to transport photo-generated electrical charges away to form output current. Transparent conductive oxides (TCOs) are used as front contacts in some embodiments. In some other embodiments, front contact layer 110 is made of a transparent conductive coating comprising nanoparticles such as metal nanoparticles or nanotube such as carbon nanotubes (CNT). Both high electrical conductivity and high optical transmittance of the transparent conductive layer are desirable to improve photovoltaic efficiency.

Examples of a suitable material for the front contact layer 110 include but are not limited to transparent conductive oxides such as indium tin oxide (ITO), fluorine-doped tin oxide (FTO), aluminum-doped zinc oxide (AZO), gallium doped ZnO (GZO), alumina and gallium co-doped ZnO (AGZO), boron doped ZnO (BZO), and any combination thereof. A suitable material for the front contact 110 can also be a composite material comprising at least one of the transparent conductive oxide (TCO) and another conductive material, which does not significantly decrease electrical conductivity or optical transparency of front contact layer 110. The thickness of front contact layer 110 is in the order of nanometers or microns, for example in the range of from 0.3 nm to 2.5 μm in some embodiments.

As shown in FIGS. 3A-3B and 4A-4B, after photovoltaic device 100 is pre-heated to the selected temperature, front contact layer 110 can be formed using a suitable process such as chemical vapor deposition. In some embodiments, front contact layer 110 comprises boron doped zinc oxide and is formed through a chemical vapor deposition using a zinc-containing precursor and a boron-containing precursor. For example, the zinc-containing precursor comprises diethyl zinc ((C₂H₅)₂Zn) and the boron-containing precursor comprises diborane (B₂H₆) at a selected temperature in the range of from 160° C. to 180° C. (e.g., 165° C. as shown). The pressure is in the range from 0.65 torr to 1 torr. The deposition time can be in any suitable range, for example in the range of from 8 minutes to 10 minutes (e.g., 9 minutes) as shown in FIGS. 3A-3B and 4A-4B.

After step 210, the processing chamber can be vacuumed and purged with a gas. The processing chamber can be also kept at the same temperature or cooled down. The photovoltaic device can be then exposed to air, kept in the processing chamber or removed from the processing chamber for subsequent fabrication steps.

In some embodiments, an anti-reflection layer 116 (not shown) is formed over front contact layer 110. Examples of a suitable material for anti-reflection layer 116 include but are not limited to SiO₂ and MgF₂.

These processing steps can be used in any combination. For example, in some embodiments, a method of fabricating a photovoltaic device 100 can comprise the following steps: forming back contact layer 104 above substrate 102 (step 202), forming absorber layer 106 above back contact layer 104 (step 204), forming buffer layer 108 over absorber layer 106 (step 206), and pre-heating photovoltaic device 100 to a selected temperature with a thermal budget in the range of from 30,000 degree*second to 150,000 degree*second (step 208). Such a method further comprises step 210 of forming front contact layer 110 over buffer layer 108 at the selected temperature, after step 208 of pre-heating. In some embodiments, front contact layer 110 comprises a transparent conductive oxide (TCO). For example, in some embodiments, front contact layer 110 comprises boron doped zinc oxide and is formed through chemical vapor deposition using diethyl zinc and diborane at a selected temperature in a range from 160° C. to 180° C. Before the preheating step (step 208), vacuum can be applied to the processing chamber, and an inert gas such as nitrogen can be provided into the processing chamber.

The inventor has determined that heating at steps 208 and 210 (or subsequent processing steps) can affect the quality of absorber layer 106. Excessive heating may decrease carrier concentration or increase defect of absorber. The inventor has surprisingly found that a higher heating rate or a lower thermal budget used in step 208 can provide absorber layer 106 and resulting junction having significantly better quality; and significantly increase quantum efficiency (QE), module power, and irradiation performance of photovoltaic device 100.

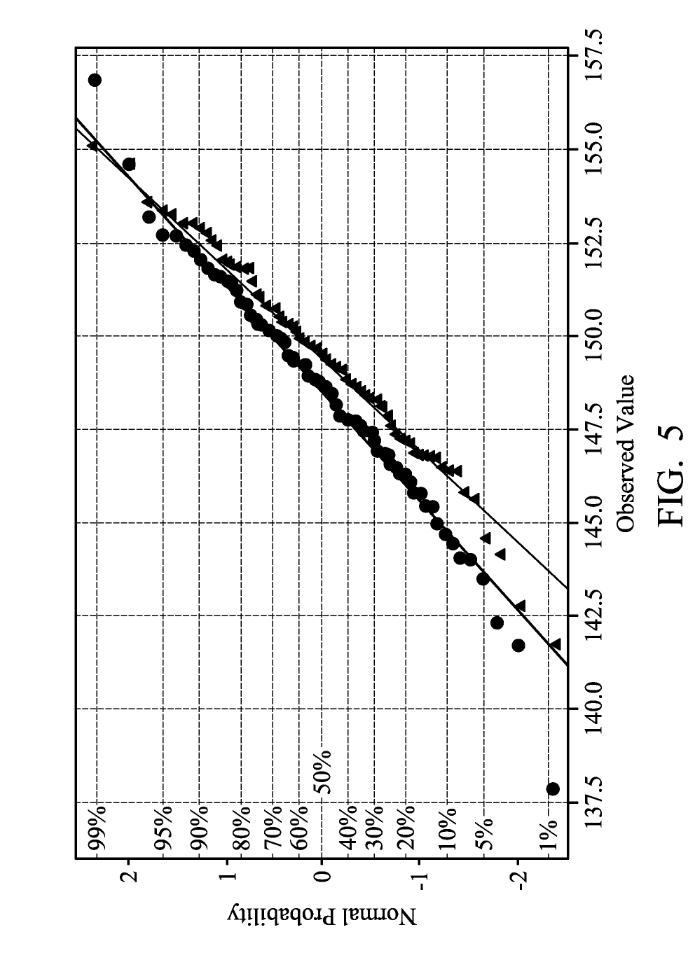

Table 1 shows results of two photovoltaic devices made using a pre-heating profile as described in FIG. 3A and FIG. 3B, respectively. The heating time in the step 208 of pre-heating photovoltaic device 100 is 16 minutes, and 10 minutes, respectively. FIG. 5 compares the results of the module power of such resulting photovoltaic devices. When a heating rate higher than 8° C./minutes or a thermal budget lower than 13,000 degree*second is used during step 208, the module power of resulting photovoltaic devices increases by about 2.2 watts. The irradiation performance increases by about 1.5%. Meanwhile, resulting front contact layer 110 (i.e. TCO) has the same quality measured by X-ray diffraction (XRD) and scanning electronic microscope (SEM). Resulting contact layer 110 also has the same performance including sheet resistance and optical transparency when a higher heating rate or a lower thermal budget is used during step 208 of pre-heating.

TABLE 1

| | Pre-heating time | Pre-heating time |
|---|---|---|
| Item | 10 Minutes | 16 Minutes |
| IV Jsc | 35.72 | 35.42 |
| QE Jsc (mA/cm²) | 34.63 | 34.13 |
| Bandgap (eV) | 1.086 | 1.085 |

The present disclosure provides a method of fabricating a photovoltaic device. The method comprises the following steps: forming an absorber layer above a substrate of the photovoltaic device, forming a buffer layer over the absorber layer, and pre-heating the photovoltaic device at a first heating rate to a selected temperature. The first heating rate is higher than 5° C./minute. The method further comprises a step of forming a front contact layer over the buffer layer at the selected temperature, after the step of pre-heating the photovoltaic device. The method can further comprise a step of forming a back contact layer above the substrate before the step of forming the absorber layer.

In some embodiments, the first heating rate is in the range from 5° C./minute to 25° C./minute. In some embodiments, the first heating rate is in the range from 6° C./minute to 22° C./minute, for example, in the range from 8° C./minute to 11° C./minute. In some embodiments, the selected temperature is in the range of from 150° C. to 200 ° C., for example, in the range of from 160° C. to 180° C. The step of forming the front contact layer can be performed through chemical vapor deposition.

In some embodiments, the front contact layer comprises boron doped zinc oxide and is formed through a chemical vapor deposition using a zinc-containing precursor and a boron-containing precursor. For example, the zinc-containing precursor comprises diethyl zinc and the boron-containing precursor comprises diborane.

In some embodiments, the method further comprises two steps: applying vacuum to a processing chamber in which the preheating step is performed, and providing an inert gas into the processing chamber, before the step of preheating the photovoltaic device.

In some embodiments, the present disclosure provides a method of fabricating a photovoltaic device. The method comprises the following steps: forming an absorber layer above a substrate of the photovoltaic device, forming a buffer layer over the absorber layer, and pre-heating the photovoltaic device to a selected temperature, with a thermal budget less than 150,000 degree*second. The thermal budget is defined as an integral of temperature with respect to time during the pre-heating. The method further comprises a step of forming a front contact layer over the buffer layer at the selected temperature, after the step of pre-heating the photovoltaic device.

In some embodiments, the thermal budget is in the range of from 30,000 degree*second to 150,000 degree*second, for example, in the range of from 35,000 degree*second to 125,000 degree*second. In some embodiments, the thermal budget is in the range of from 70,000 degree*second to 90,000 degree*second.

In some embodiments, the front contact layer comprises boron doped zinc oxide and is formed through chemical vapor deposition using a zinc-containing precursor and a boron-containing precursor. For example, the front contact layer can be formed through chemical vapor deposition using diethyl zinc and diborane at a selected temperature in the range of from 160° C. to 180° C.

The present disclosure also provide a method of fabricating a photovoltaic device, comprising the following steps: forming a back contact layer above a substrate, forming an absorber layer above the back contact layer, forming a buffer layer over the absorber layer, and pre-heating the photovoltaic device to a selected temperature with a thermal budget in the range of from 30,000 degree*second to 150,000 degree*second. The thermal budget is defined as an integral of temperature with respect to time during the pre-heating. The method further comprises a step of forming a front contact layer over the buffer layer at the selected temperature, after the step of pre-heating.

In some embodiments, the front contact layer comprises a transparent conductive oxide. For example, in some embodiments, the front contact layer comprises boron doped zinc oxide and is formed through chemical vapor deposition using diethyl zinc and diborane, and the selected temperature is in a range from 160° C. to 180° C. The method can further comprise two steps: applying vacuum to a processing chamber in which the pre-heating is performed, and providing an inert gas into the processing chamber, before the preheating.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a photovoltaic device, comprising
forming an absorber layer above a substrate of the photovoltaic device;
forming a buffer layer over the absorber layer;
pre-heating the photovoltaic device at a first heating rate to a selected temperature, the first heating rate being higher than 5° C./minute; and
forming a front contact layer over the buffer layer at the selected temperature, after the step of pre-heating the photovoltaic device.

2. The method of claim 1, further comprising:
forming a back contact layer above the substrate before the step of forming the absorber layer.

3. The method of claim 1, wherein
the first heating rate is in the range from 5° C./minute to 25° C./minute.

4. The method of claim 1, wherein
the first heating rate is in the range from 6° C./minute to 22° C./minute.

5. The method of claim 1, wherein
the first heating rate is in the range from 8° C./minute to 11° C./minute.

6. The method of claim 1, wherein
the selected temperature is in the range of from 150° C. to 200° C.

7. The method of claim 1, wherein
the step of forming the front contact layer is performed through chemical vapor deposition.

8. The method of claim 1, wherein
the front contact layer comprises boron doped zinc oxide and is formed through a chemical vapor deposition using a zinc-containing precursor and a boron-containing precursor.

9. The method of claim 8, wherein
the zinc-containing precursor comprises diethyl zinc and the boron-containing precursor comprises diborane.

10. The method of claim 1, further comprising
applying vacuum to a processing chamber in which the preheating step is performed; and
providing an inert gas into the processing chamber, before the step of preheating the photovoltaic device.

11. A method of fabricating a photovoltaic device, comprising
forming an absorber layer above a substrate of the photovoltaic device;
forming a buffer layer over the absorber layer;
pre-heating the photovoltaic device to a selected temperature, with a thermal budget less than 150,000 degree*second, where the thermal budget is defined as an integral of temperature with respect to time during the pre-heating; and
forming a front contact layer over the buffer layer at the selected temperature, after the step of pre-heating the photovoltaic device.

12. The method of claim 11, wherein
the thermal budget is in the range of from 30,000 degree*second to 150,000 degree*second.

13. The method of claim 11, wherein
the thermal budget is in the range of from 35,000 degree*second to 125,000 degree*second.

14. The method of claim 11, wherein
the thermal budget is in the range of from 70,000 degree*second to 90,000 degree*second.

15. The method of claim 11, wherein
the front contact layer comprises boron doped zinc oxide and is formed through chemical vapor deposition using a zinc-containing precursor and a boron-containing precursor.

16. The method of claim 15, wherein
the front contact layer is formed through chemical vapor deposition using diethyl zinc and diborane at a selected temperature in the range of from 160° C. to 180° C.

17. A method of fabricating a photovoltaic device, comprising
forming a back contact layer above a substrate;
forming an absorber layer above the back contact layer;
forming a buffer layer over the absorber layer;
pre-heating the photovoltaic device to a selected temperature with a thermal budget in the range of from 30,000 degree*second to 150,000 degree*second, the thermal budget defined as an integral of temperature with respect to time during the pre-heating ; and
forming a front contact layer over the buffer layer at the selected temperature, after the step of pre-heating.

18. The method of claim 17, wherein
the front contact layer comprises a transparent conductive oxide.

19. The method of claim 17, wherein
the front contact layer comprises boron doped zinc oxide and is formed through chemical vapor deposition using diethyl zinc and diborane, and the selected temperature is in a range from 160° C. to 180° C.

20. The method of claim 17, further comprising
applying vacuum to a processing chamber in which the pre-heating is performed; and
providing an inert gas into the processing chamber, before the preheating.
